(19) United States
(12) Patent Application Publication
(10) Pub. No.: US 2024/0088008 A1
(43) Pub. Date: Mar. 14, 2024

(54) FAN-OUT PACKAGING UNIT USED IN POP PACKAGING AND METHOD FOR MANUFACTURING SAME

(71) Applicant: SJ Semiconductor(Jiangyin) Corporation, Jiangyin City (CN)

(72) Inventors: Yenheng CHEN, Jiangyin City (CN); Chengchung LIN, Jiangyin City (CN)

(73) Assignee: SJ Semiconductor(Jiangyin) Corporation, Jiangyin City, JS (CN)

(21) Appl. No.: 18/367,477

(22) Filed: Sep. 13, 2023

(30) Foreign Application Priority Data
Sep. 13, 2022 (CN) 2022111117189

(51) Int. Cl. H01L 23/498; H01L 21/48; H01L 23/00; H01L 23/15; H01L 25/065

(52) U.S. Cl. CPC H01L 23/49833; H01L 21/4857; H01L 21/486; H01L 23/15; H01L 23/49816; H01L 23/49822; H01L 23/49838; H01L 24/08; H01L 24/80; H01L 25/0655; H01L 23/49866; H01L 2224/08225; H01L 2224/80006; H01L 2224/80895; H01L 2224/80896; H01L 2924/3512; H01L 2924/381

(57) ABSTRACT

A fan-out packaging unit of Package-on-Package (PoP) structure and a method for manufacturing the same are disclosed. The method includes steps of: forming a first rewiring layer on a substrate; forming a hybrid bonding structure between a first surface of the first rewiring layer and semiconductor chips, wherein the hybrid bonding structure comprises a first bonding layer formed on the first surface of the first rewiring layer; forming a plastic layer on the first surface of the first rewiring layer to form a packaging layer, which covers the semiconductor chips; and forming a second rewiring layer over a second surface of the first rewiring layer, wherein the second rewiring layer comprises a second metal wiring layer exposed from the first surface of the second rewiring layer. The resulting fan-out packaging unit has an all-inorganic first rewiring layer instead of a TSV interposer, reducing the cost of package manufacturing and optimizing the package size.

### CROSS REFERENCE TO RELATED APPLICATION

The present application claims the benefit of priority to Chinese Patent Application No. CN 202211111718.9, entitled “FAN-OUT PACKAGING UNIT USED IN PoP PACKAGING AND METHOD FOR MANUFACTURING SAME”, filed with CNIPA on Sep. 13, 2022, the disclosure of which is incorporated herein by reference in its entirety for all purposes.

### FIELD OF THE INVENTION

The present disclosure generally relates to the field of semiconductor packaging and relates to a fan-out packaging structure used in Package-on-Package (PoP) packaging and a method for manufacturing the same.

### BACKGROUND OF THE INVENTION

As mobile consumer electronics such as smart phones, personal digital assistants (PDAs), and digital cameras demand higher levels of integration, larger storage space, miniaturization, and reliability in packaging, integrating multiple high-density chips into a powerful yet compact system or subsystem has become a major challenge in advanced semiconductor chip packaging.

System-In-Package (SIP) technology is an emerging heterogeneous integration technology that can integrate multiple active and passive devices, micro-electromechanical systems (MEMS), and/or optical components into a single package to form a system or subsystem with multiple functions. This has made it an increasingly popular packaging option for many chips. Currently, chips with different performance levels are first prepared using front end of line (FEOL) processes and are then attached to a through-silicon-via (TSV) interposer. The ultra-fine pins of the chips are then interconnected through the TSV interposer to form a functional module or system. However, this technology can be expensive, limiting its range of applications.

Additionally, as the demand for packaging components and functionality increases, existing system-level packaging structures may occupy larger areas and volumes, hindering further integration.

### SUMMARY

The present disclosure provides a method for manufacturing a fan-out packaging unit used in PoP packaging, comprising: forming a first rewiring layer on a supporting substrate, the first rewiring layer having a first surface and a second surface opposite to the first surface, wherein the first rewiring layer comprises at least one inorganic dielectric layer and at least one first metal wiring layer; forming a hybrid bonding structure between the first surface of the first rewiring layer and semiconductor chips to electrically couple the semiconductor chips to the first surface of the first rewiring layer, wherein the hybrid bonding structure comprises a first bonding layer formed on the first surface of the first rewiring layer; forming a plastic layer on the first surface of the first rewiring layer to form a packaging layer covering the semiconductor chips; and forming a second rewiring layer over the second surface of the first rewiring layer, the second rewiring layer having a first surface and a second surface opposite to the first surface, wherein the second rewiring layer comprises a second metal wiring layer exposed by the first surface of the second rewiring layer, wherein the second metal wiring layer is electrically connected to the second surface of the first rewiring layer.

The present disclosure also provides a fan-out packaging unit used in PoP packaging, comprising: a rewiring layer having a first surface and a second surface opposite to the first surface, wherein a first bonding layer is provided on the first surface of the rewiring layer, and the rewiring layer comprises at least two inorganic dielectric layers and at least two metal wiring layers alternately formed; a hybrid bonding structure, disposed on the first surface of the first rewiring layer and electrically coupling semiconductor chips to the first surface of the first rewiring layer for interconnection between the semiconductor chips through the first rewiring layer, wherein the semiconductor chips are covered by a plastic layer to form a packaging layer; and a second rewiring layer having a first surface and a second surface opposite to the first surface, wherein the second rewiring layer comprises a second metal wiring layer exposed by the first surface of the second rewiring layer, wherein the second metal wiring layer is electrically connected to the second surface of the first rewiring layer, to achieve electrical lead-out of the semiconductor chips and the first rewiring layer.

The fan-out packaging unit and method for manufacturing the same have the following beneficial effects:

In the fan-out packaging unit used in PoP packaging of the present disclosure, the hybrid bonding structure is used to bond the first rewiring layer to the semiconductor chips without any solder, avoiding cracks in the solder at the interface between the two, improving the reliability of interconnection, achieving a high-performance system-level fan-out packaging structure, and also reducing the pitch between two pins, thereby increasing the density of I/O ports, which is conducive to miniaturization of the packaging structure.

In the fan-out packaging unit of the present invention, heterogeneous integration and interconnection of multiple chips can be achieved without using a TSV interposer, reducing packaging cost; in addition, the second rewiring layer is used to replace a packaging substrate, and is electrically coupled to external chips or packaging units through conductive interconnections, to finally obtained an integrated POP packaging structure.

In the method for manufacturing the fan-out packaging unit of the present disclosure, by using inorganic dielectric materials for insulating the first rewiring layer, the line spacing within the first rewiring layer is reduced to less than 1 μm, and hybrid bonding is achieved at the interface between the first rewiring layer and the semiconductor chips. This arrangement avoids forming interfaces between organic and inorganic materials, improves process integration in packaging manufacturing, and minimizes package volume.

### BRIEF DESCRIPTION OF THE DRAWINGS

FIG. 1 shows a flow chart illustrating a method for manufacturing a fan-out packaging unit of the present disclosure.

FIG. 2 shows a schematic diagram of an intermediate structure obtained after forming an inorganic dielectric layer on a supporting substrate according to one embodiment of the present disclosure.

FIG. 3 shows a schematic diagram of an intermediate structure obtained after forming contact pads on the supporting substrate according to one embodiment of the present disclosure.

FIG. 4 shows a schematic diagram of an intermediate structure obtained after forming a first rewiring layer according to one embodiment of the present disclosure.

FIG. 5A shows a schematic diagram of an intermediate structure obtained after forming a first bonding layer on a first surface of the first rewiring layer according to one embodiment of the present disclosure.

FIG. 5B shows a schematic diagram of an intermediate structure obtained after forming a second bonding layer on surfaces of semiconductor chips according to one embodiment of the present disclosure.

FIG. 6 shows a schematic diagram of an intermediate structure obtained after forming a hybrid bonding structure between the first surface of the first rewiring layer and the semiconductor chips according to one embodiment of the present disclosure.

FIG. 7 shows a schematic diagram of an intermediate structure obtained after forming a plastic layer over the first surface of the first rewiring layer according to one embodiment of the present disclosure.

FIG. 8 shows a schematic diagram of an intermediate structure obtained after thinning the plastic layer according to one embodiment of the present disclosure.

FIG. 9 shows a schematic diagram of an intermediate structure obtained after removing the supporting substrate according to one embodiment of the present disclosure.

FIG. 10 shows a schematic diagram of an intermediate structure obtained after forming a second bonding layer on a second surface of a second rewiring layer according to one embodiment of the present disclosure.

FIG. 11 shows a schematic diagram of an intermediate structure obtained after forming solder balls inside openings of the second rewiring layer according to one embodiment of the present disclosure.

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

Refer to FIGS. 1-11. It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

The present disclosure provides a method for manufacturing a fan-out packaging unit used in PoP packaging. FIG. 1 is a flow chart illustrating the method, comprising steps S1-S5:
S1: providing a supporting substrate, forming a first rewiring layer on the supporting substrate, wherein the first rewiring layer comprises at least one inorganic dielectric layer and at least one first metal wiring layer;
S2: forming a hybrid bonding structure between a first surface of the first rewiring layer and semiconductor chips to electrically couple the semiconductor chips to the first surface of the first rewiring layer;
S3: forming a plastic layer on the first surface of the first rewiring layer to form a packaging layer covering the semiconductor chips;
S4: removing the supporting substrate to expose a second surface of the first rewiring layer;
S5: forming a second rewiring layer over the second surface of the first rewiring layer, wherein the second rewiring layer comprises a second metal wiring layer exposed by a first surface of the second rewiring layer.

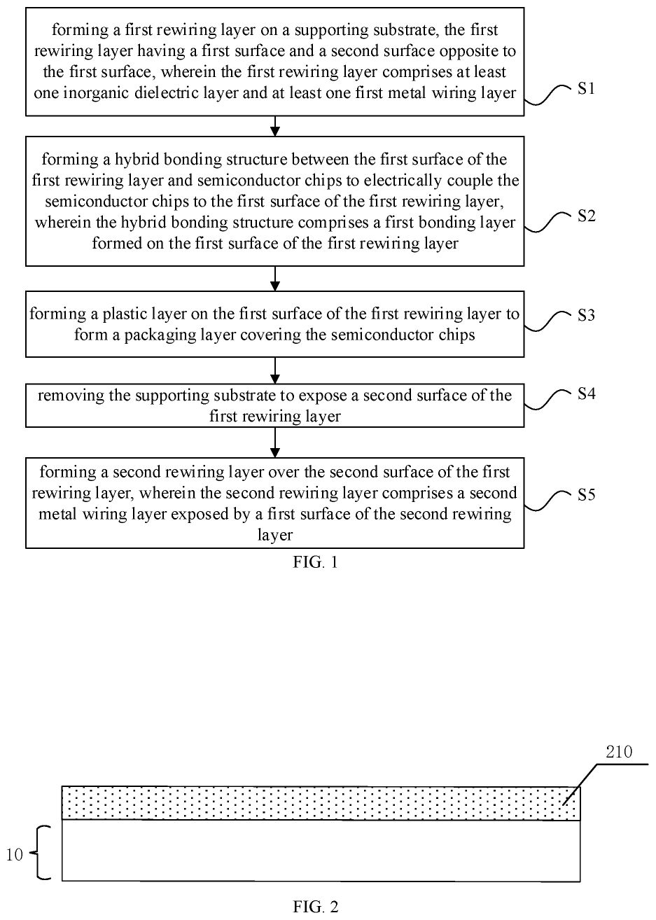

First, as shown in FIGS. 1 to 2, step S1 is performed by forming the first rewiring layer 20 on the supporting substrate 10. Specifically, the supporting substrate 10 is used to prevent layered packaging structures formed upon it from cracking, warping, fracturing, etc. during the packaging process, and the supporting substrate 10 may a wafer, a panel, or of any other desired shape, and it can be made of materials such as silicon, glass, metal, semiconductor, polymer, and ceramics. In one example, the supporting substrate 10 is a silicon-based substrate, to reduce packaging cost.

Referring to FIG. 2, step S1 comprises: a first substep S1-1, forming a second inorganic dielectric layer 210 on the supporting substrate 10, and then forming a plurality of via-holes (not shown) in the second inorganic dielectric layer 210 by laser etching or similar processes to obtain a patterned second inorganic dielectric layer 211.

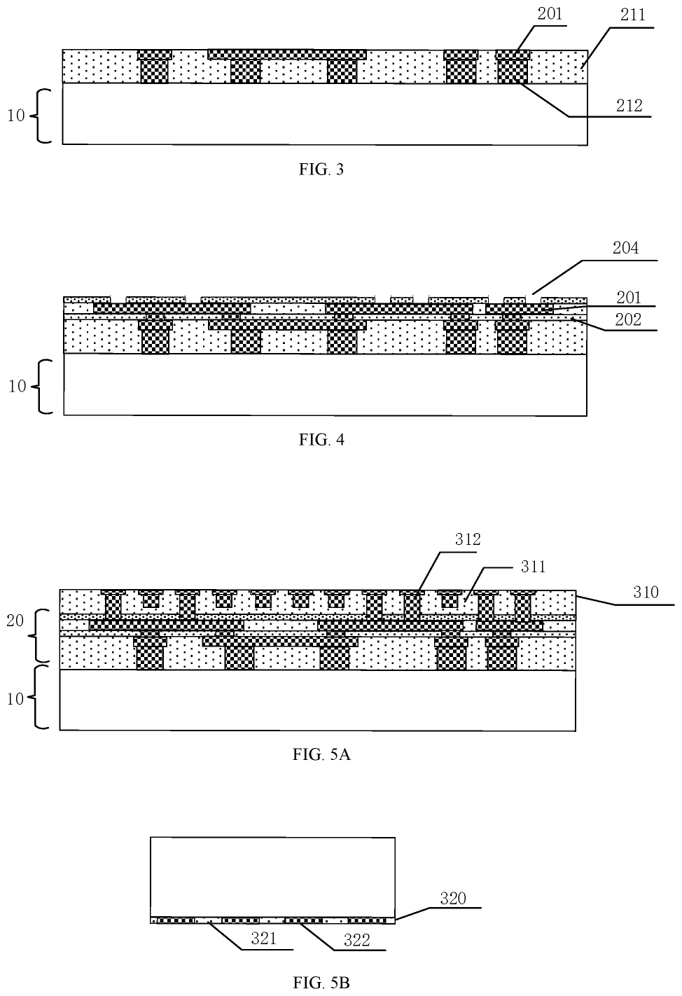

Referring to FIG. 3, step S1 further comprises: a second sub-step S1-2, forming a first metal wiring layer 201 in the patterned second inorganic dielectric layer 211.

Specifically, at steps S1-2, contact pads 212 are formed in the via-holes using sputtering, electroplating, chemical plating, or other suitable processes, and a first metal material layer is formed over the patterned second inorganic dielectric layer 211; the first metal material layer is then patterned using an etching process to obtain a first metal wiring layer 201; the first metal wiring layer 201 is made of one or more of copper, aluminum, nickel, gold, silver, and titanium. Preferably, the first metal wiring layer 201 is made of copper.

Referring to FIG. 4, step S1 further comprises: a third sub-S1-3, forming a first patterned inorganic dielectric layer 202 over the first metal wiring layer 201.

Specifically, step S1-3 comprises: forming a first inorganic dielectric layer over the first metal wiring layer 201 using chemical vapor deposition, physical vapor deposition, or other suitable process, and etching the first inorganic dielectric layer to form the first patterned inorganic dielectric layer 202, the first inorganic dielectric layer may be made of a material that is harder than that of the second inorganic dielectric layer, which comprises, but not limited to, one of silicon nitride and silicon nitride oxide.

In one example, a material of the first inorganic dielectric layer is silicon nitride, and a material of the second inorganic dielectric layer is silicon oxide, which will reduce damage to the first inorganic dielectric layer caused by etching and reduce the difficulty of manufacturing the first rewiring layer.

Specifically, the steps of forming the first rewiring layer 20 also comprise: using a process comprising but not limited to vapor deposition to form the first inorganic dielectric layer 202 over the first metal wiring layer 201, and then using photolithography etching to form patterned areas or via-holes in the first inorganic dielectric layer 202. After that, using one or more of sputtering, electroplating, and chemical plating to form a metal material layer on the patterned areas or via-holes and on the first inorganic dielectric layer 202 to form another first metal wiring layer 201; that is, the steps of forming a first patterned inorganic dielectric layer 202 and forming a first metal wiring layer 201 may be performed more than once. Interconnection between different first metal wiring layers is achieved by patterning the several inorganic dielectric layers or forming via-holes in the several inorganic dielectric layers; it should be noted that the number of the first metal wiring layers and the inorganic dielectric layers can be adjusted to achieve different wiring functions, as long as the first metal wiring layers are electrically connected to each other (when there are two or more first metal wiring layers); the fact that each of the first rewiring layers has an inorganic wiring layer reduces the line spacing of the first rewiring layers to below 1 μm, and also avoids the formation of an interface between organic and inorganic materials.

In an example as shown in the figures, the first rewiring layer 20 comprises two first inorganic dielectric layers and two first metal wiring layers, and the upper one of the first inorganic dielectric layers 202 is provided with via-holes 204 partially revealing a first metal wiring layer beneath.

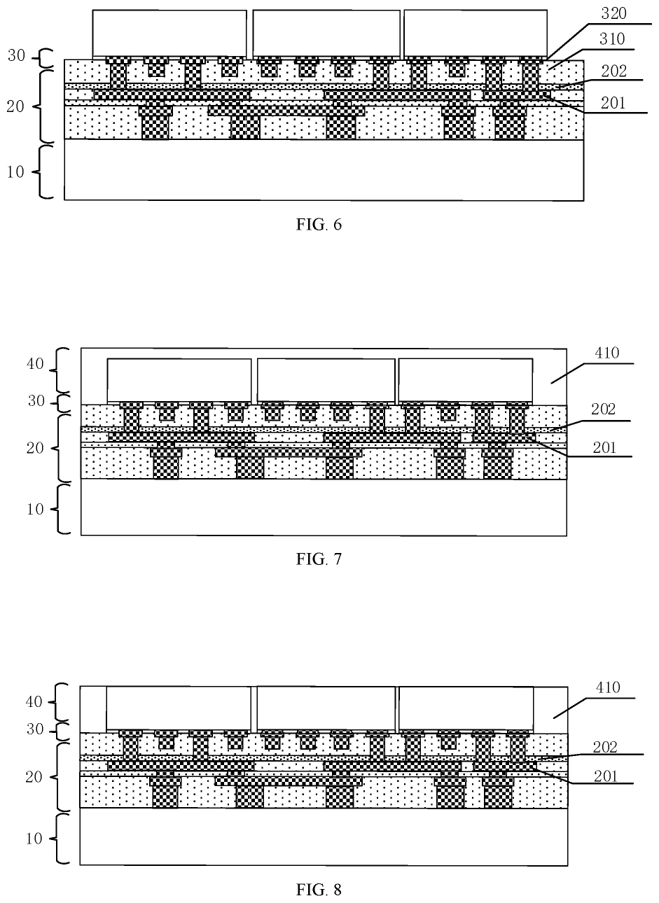

Referring to FIGS. 5A, 5B and 6, step S2 comprises: forming the hybrid bonding structure 30 between the first surface of the first rewiring layer and the semiconductor chips.

As an example, step S2 comprises: a first sub-S2-1, forming a first bonding layer 310 on the first surface of the first rewiring layer 20; and a second sub-S2-2, aligning and directly bonding first pads 312 to second pads 322 on the semiconductor chips.

Specifically, as shown in FIGS. 5A to 5B, sub-step S2-1 comprises: forming a first passivation layer 311 on the first surface of the first rewiring layer 20; forming openings in the first passivation layer 311 by a photolithography process and an etching process, and filling metal in the openings to form the first pads 312 embedded in the first passivation layer 311, to complete the first bonding layer 310. The first bonding layer 310 comprises the first passivation layer 311, and the first pads 312.

As an example, metal is disposed on the first passivation layer 311 using sputtering, electroplating, chemical plating, or other suitable processes to form the first pads 312; meanwhile the metal enters the via-holes 204 to form conductive plugs, thereby achieving electrical connection between the first bonding layer 310 and the first rewiring layer 20. As shown in FIG. 5A, the first passivation layer 311 is formed on the uppermost one of the first inorganic dielectric layers 211; the openings in the first passivation layer 311 are formed by a photolithography process and an etching process, thereby obtaining a patterned first passivation layer, and revealing the via-holes 204 in the first inorganic dielectric layer; the patterned first passivation layer is filled with metal to form the first pads 312 embedded in the patterned first passivation layer. By defining the size and location of the first pads on the first passivation layer 311 by a photolithographic process, the line spacing/pitch between pins can be adjusted and the density of the I/O ports can be increased.

In one example, the first passivation layer 312 is made of the same material as the second inorganic dielectric layer, while in other examples, the first passivation layer 312 is made of a different material than the second inorganic dielectric layer. In one example, the first passivation layer may be made of one of silicon oxide and silicon nitride. Accordingly, as shown in FIG. 5B, a surface of the semiconductor chips is provided with a second bonding layer 320, and the second bonding layer 320 comprises a second passivation layer 321 and second pads 322 embedded in the second passivation layer 321.

Specifically, the second sub-step S2-2 comprises: aligning and directly bonding the first pad 312 to the second pads 322 on the semiconductor chips. In one example, the first passivation layer and the second passivation layer are hydrophilically bonded, while the first pads 312 are aligned with and directly bonded to the second pads 322, thereby forming a hybrid bonding structure between the semiconductor chips and the first rewiring layer, using no solder, and avoiding cracks caused by solder at the interface between the two.

As an example, the first pads 312 and the second pads 322 are made of the same material. Preferably, the first pads 312 and the second pads 322 are made of copper, resulting in Cu—Cu bonded interconnections with better electrical conductivity and better resistance to electromigration.

Referring to FIG. 6, step S3 comprises: forming a plastic layer 410 on the first surface of the first rewiring layer 20 to form a packaging layer 40 covering the semiconductor chips;

As an example, the semiconductor chips may be functional chips, which comprise active devices as well as passive devices, achieving heterogeneous integration of active and passive devices, thereby forming a package that implements a specific function.

As an example, the method of forming the plastic layer 410 comprises, but is not limited to, one of compression molding, transfer molding, liquid seal molding, vacuum lamination, and spin coating; and the plastic layer may be made of a curable material, such as a polymer-based material, a resin-based material, an epoxy resin, a liquid thermosetting epoxy resin, a plastic compound, a polyamide, and any combination thereof. Referring to FIG. 8, after forming the plastic layer 410, a step of thinning the plastic layer 410 may also be performed, and may comprise, for example, using a chemical mechanical polishing (CMP) process to flatten the plastic layer 410 and reduce the thickness of the entire packaging structure.

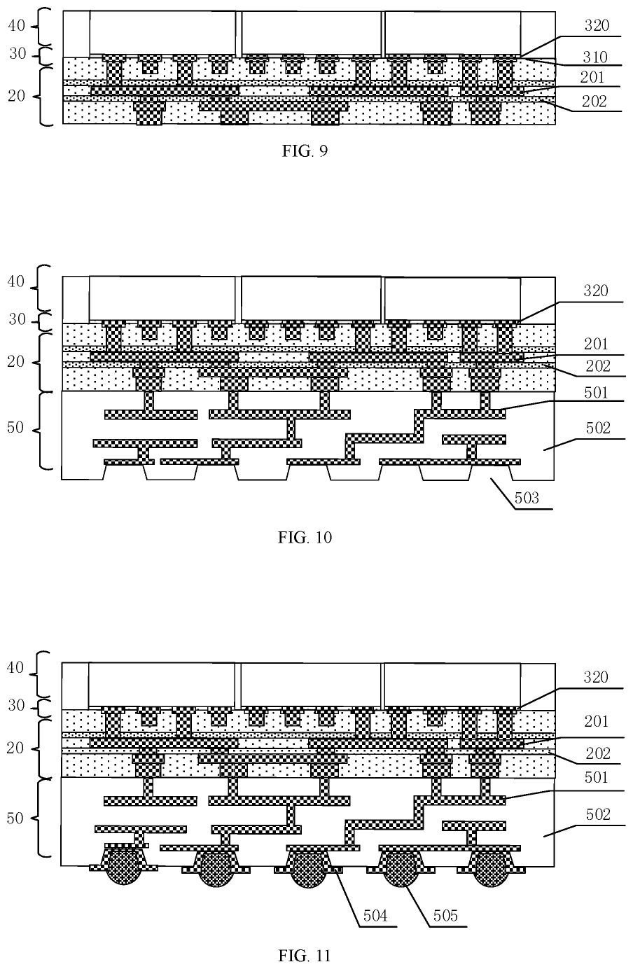

Referring to FIG. 9, step S4 comprises: removing the supporting substrate 10 to expose the second surface of the first rewiring layer 20.

Specifically, the step S4 of removing the supporting substrate 10 comprises: performing a CMP process or etching on the supporting substrate 10. By removing the supporting substrate 10, the contact pads 212 and the patterned second inorganic dielectric layer 211 are revealed; the supporting substrate 10 is a silicon-based substrate.

Referring to FIGS. 10 to 11, step S5 is performed by: forming a second rewiring layer 50 on the second surface of the first rewiring layer 20, wherein the second rewiring layer 50 comprises a second metal wiring layer 501 and an organic dielectric layer 502 on top of the second metal wiring layer 501, wherein the second metal wiring layer 501 is exposed by a first surface of the second rewiring layer 50.

Specifically, a material of the organic dielectric layer may be one or plating, more of epoxy resin, silicone, polyimide (PI), Polybenzoxazole (PBO), and Benzocyclobutene (BCB). As an example, the organic dielectric layer 502 is made of PI to further reduce the process difficulty as well as the process cost.

As an example, the second metal wiring layer is made of the same material as the first metal wiring layer; preferably, the second metal wiring layer is made of copper, so that main components of the packaging unit are electrically connected by copper, which leads to optimized electrical properties and better resistance to electromigration.

As an example, step S4 also comprises: after forming the organic dielectric layer, forming an array of solder balls over the second surface of the second rewiring layer, for achieving electrical interconnection between the fan-out packaging unit and an external chip or an external packaging unit, Specifically, step S4 comprises: forming openings 503 on the second surface of the second rewiring layer 50 to expose the second metal wiring layer; forming a sub-bump metal layer 504 over the openings 503; and forming the solder balls 505 inside the openings 503 by a ball planting reflow process. Although in the above examples the electrical interconnection between the fan-out packaging unit and external components is achieved based on the solder balls, other approaches such as metal bumps, solder bumps are also applicable.

The present disclosure also provides a fan-out packaging unit used in PoP packaging, comprising: a first rewiring layer 20, a hybrid bonding structure 30, and a second rewiring layer 50, wherein the first rewiring layer 20 has a first surface and a second surface opposite to each other, and the hybrid bonding structure 30 is located over the first surface of the first rewiring layer 20 for electrically coupling semiconductor chips to the first surface of the first rewiring layer 20. Specifically, the first rewiring layer 20 comprises at least two inorganic dielectric layers 202 and at least two metal wiring layers 201 alternately formed; the semiconductor chips are covered by a plastic layer 410 to form a packaging layer 40; the second rewiring layer 50 comprises a second metal wiring layer 501 exposed by the first surface of the second rewiring layer 50, wherein the second metal wiring layer 501 is electrically connected to the second surface of the first rewiring layer 20, to achieve electrical lead-out of the semiconductor chips and the first rewiring layer 20.

As an example, the first rewiring layer 20 comprises one or more first inorganic dielectric layers 202 and one or more first metal wiring layers 201; the first inorganic dielectric layers and the first metal wiring layers are alternately formed and arranged along the vertical direction. Here, the first rewiring layer 20 uses inorganic dielectric materials as its insulating materials, and is configured as an inorganic-material-based wiring layer, which can reduce the line spacing within the first rewiring layer 20 to less than 1 μm, minimize the package volume, replace TSV adapters, and reduce the manufacturing cost.

As an example, a material of the first inorganic dielectric layer(s) is different from a material of the second inorganic dielectric layer; for example, the first inorganic dielectric layer(s) are made of silicon oxide and the second inorganic dielectric layer is made of silicon nitride.

As an example, the contact pads 212 are exposed by the second surface 20 of the first rewiring layer, and electrically connected to the second metal wiring layer 501 that is exposed by the first surface of the second rewiring layer 50.

As an example, the first rewiring layer 20 is provided with a first bonding layer 310 on its first surface and the semiconductor chips are provided with a second bonding layer 320 on its surface, and the hybrid bonding structure 30 comprises the first bonding layer 310, and the second bonding layer 320, wherein the first bonding layer and the second bonding layer are directly bonded without solder, and a bonding interface therebetween has an interconnection pitch of less than 10 microns

As an example, the second rewiring layer 50 further comprises an organic dielectric layer 502 on top of the second metal wiring layer 501; the first metal wiring layer may be made of the same material as the second metal wiring layer; the first metal wiring layer comprises one or more of copper, aluminum, nickel, gold, silver, and titanium; the organic dielectric layer 502 comprises one or more of epoxy resin, silicone, polyimide (PI), Polybenzoxazole (PBO), and Benzocyclobutene (BCB).

Specifically, the second surface of the second rewiring layer 50 is electrically coupled to an external chip or packaging unit through conductive interconnection, the conductive interconnect comprises an array of solder balls disposed over the second surface of the second rewiring layer 50, and the solder balls 505 are disposed over a sub-bump metal layer 504.

In some examples, the semiconductor chips may be functional chips, which comprise active devices, such as logic devices, high bandwidth memory devices, switches, power management units, and surface mounted devices; and passive devices, such as resistors, inductors, capacitors, etc.

As shown in FIG. 11, the fan-out packaging unit used in PoP packaging can be a SIP module that can integrate a processor, sensor, data encryption chip, actuator, memory, connector, and security chip. These active and passive devices are arranged side by side and are electrically connected to the rewiring layer 20 by the hybrid bonding structure 30, wherein two or more heterogeneous semiconductor components and passive devices are integrated into a standard package to achieve substantially complete functionality using the hybrid bonding structure 30, thereby allowing more flexibility in customizing the packaging structure for desired functions.

The present disclosure also provides a PoP packaging structure, comprising: at least one fan-out packaging unit as previously described, wherein the at least one fan-out packaging unit is stacked over each other on a packaging substrate. Specifically, the fan-out packaging unit can be arranged in a stack with an external chip or packaging unit.

In summary, the fan-out packaging unit used in PoP packaging of the present disclosure adopts an all-inorganic first rewiring layer instead of conventionally used TSV interposers, which reduces the manufacturing cost, achieves a high-performance fan-out packaging structure; the hybrid bonding structure is used to bond the first rewiring layer to the semiconductor chips without solder, avoiding cracks in the solder at the interface between the two, improving the reliability of interconnection, and also reducing the pitch between pins, thereby increasing the density of I/O ports, which is conducive to miniaturization of the packaging structure; in addition, the second rewiring layer is used to replace a packaging substrate, and is electrically coupled to an external chip or packaging unit through conductive interconnections, to finally obtained an integrated POP packaging structure.

In the method for manufacturing the fan-out packaging unit of the present disclosure, by using inorganic dielectric materials for insulating the first rewiring layer, the line spacing within the first rewiring layer is reduced to less than 1 μm, and hybrid bonding is achieved at the interface between the first rewiring layer and the semiconductor chips. This avoids forming interfaces between organic and inorganic materials, improves process integration in packaging manufacturing, and minimizes package volume. Therefore, the present disclosure effectively overcomes various shortcomings in the existing technology and has high industrial utilization value.

The above-mentioned embodiments are just used for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for manufacturing a fan-out packaging unit, comprising:
forming a first rewiring layer on a supporting substrate, wherein the first rewiring layer has a first surface and a second surface opposite to the first surface, wherein the first rewiring layer comprises at least one inorganic dielectric layer and at least one first metal wiring layer;
forming a hybrid bonding structure between the first surface of the first rewiring layer and semiconductor chips to electrically couple the semiconductor chips to the first surface of the first rewiring layer, wherein the hybrid bonding structure comprises a first bonding layer formed on the first surface of the first rewiring layer;
forming a plastic layer on the first surface of the first rewiring layer to form a packaging layer on the semiconductor chips; and
forming a second rewiring layer over the second surface of the first rewiring layer, wherein the second rewiring layer has a first surface and a second surface opposite to the first surface, wherein the second rewiring layer comprises a second metal wiring layer exposed from the first surface of the second rewiring layer, and wherein the second metal wiring layer is electrically connected to the second surface of the first rewiring layer.

2. The method for manufacturing the fan-out packaging unit according to claim 1, wherein the first rewiring layer comprises two or more inorganic first dielectric layers and two or more first metal wiring layers, wherein the two or more metal wiring layers are arranged alternately with the two or more inorganic first dielectric layers.

3. The method for manufacturing the fan-out packaging unit according to claim 1, further comprising: thinning the supporting substrate by applying a mechanical grinding process, and then removing the thinned supporting substrate by applying a chemical-mechanical polishing process, wherein the supporting substrate is a silicon-based substrate.

4. The method for manufacturing the fan-out packaging unit according to claim 1, wherein the first bonding layer is formed on the first surface of the first rewiring layer by:
forming a first passivation layer on the first surface of the first rewiring layer;
forming via-holes in the first passivation layer by a photolithography process and an etching process; and
filling the via-holes with metal to form first pads.

5. The method for manufacturing the fan-out packaging unit according to claim 1, wherein a material of the at least one inorganic dielectric layer comprises one of silicon nitride and silicon oxynitride, and wherein a material of the at least one first metal wiring layer comprises one or more of copper, aluminum, nickel, gold, silver, and titanium.

6. The method for manufacturing the fan-out packaging unit according to claim 1, wherein forming the second rewiring layer comprises:
forming openings on the second surface of the second rewiring layer to expose the second metal wiring layer;
forming a sub-bump metal layer over the openings; and
forming solder balls inside the openings by a ball planting reflow process.

7. A fan-out packaging unit, comprising:
a first rewiring layer having a first surface and a second surface opposite to the first surface, a first bonding layer provided on the first surface of the first rewiring layer, wherein the first rewiring layer comprises at least two inorganic dielectric layers and at least two metal wiring layers, wherein the at least two metal wiring layers are arranged alternately with the at least two inorganic dielectric layers;
a hybrid bonding structure, wherein the hybrid bonding structure is disposed on the first surface of the first rewiring layer and electrically interconnects between semiconductor chips and the first surface of the first rewiring layer;
a packaging layer disposed on the semiconductor chips, wherein the packaging layer comprises a plastic layer; and
a second rewiring layer having a first surface and a second surface opposite to the first surface, wherein the second rewiring layer comprises a second metal wiring layer exposed from the first surface of the second rewiring layer, wherein the second metal wiring layer is electrically connected to the second surface of the first rewiring layer, to achieve electrical lead-out of the semiconductor chips and the first rewiring layer.

8. The fan-out packaging unit according to claim 7, further comprising an array of solder balls disposed over the second surface of the second rewiring layer, wherein the array of solder balls is disposed on a sub-bump metal layer, and wherein the array of solder balls electrically interconnects between the fan-out packaging unit and an external chip or an external packaging unit.

9. The fan-out packaging unit according to claim 7, wherein the first bonding layer and a second bonding layer are arranged in the hybrid bonding structure, wherein the second bonding layer is attached to at least one surface of each of the semiconductor chips, wherein the first bonding layer and the second bonding layer are directly bonded, and a bonding interface therebetween has an interconnection pitch of less than 10 microns.

10. The fan-out packaging unit according to claim 7, wherein the semiconductor chips comprise an active device and a passive device arranged side by side.

11. A Package-on-Package (PoP) packaging structure, comprising one or more fan-out packaging units each according to claim 7, wherein the one or more fan-out packaging units are stacked over each other on a packaging substrate.
